(19) United States
(12) Patent Application Publication
(10) Pub. No.: US 2009/0016423 A1
(43) Pub. Date: Jan. 15, 2009

(54) Equalizer and a Method for Filtering a Signal

(75) Inventor: Alexander A. Semjonov, Leningradskaya (RU)

Correspondence Address: Motorola, Inc.;Law Department, 1303 East Algonquin Road, 3rd Floor, Schaumburg, IL, 60196, US

(73) Assignee: MOTOROLA, INC., SCHAUMBURG, IL (US)

(21) Appl. No.: 12/171,648

(22) Filed: Jul. 11, 2008

(30) Foreign Application Priority Data
Jan. 10, 2006 (RU) PCT/RU2006/000003

(51) Int. Cl. H03H 7/30

(52) U.S. Cl. 375/233; 375/232

(57) ABSTRACT

An equalizer comprising memory for storing a set of filter tap coefficients for defining the filtering characteristics to be applied to an input signal; and means for updating the set of filter tap coefficients based on an error signal derived from a difference between a received signal and a filtered signal unless an error code associated with a received data packet indicates an error in the received data packet.

The present invention relates to an equalizer and a method for filtering a signal.

Typically electronic equipment capable of receiving a communication call will include an equalizer to aid removal of distortion resulting from the effects of the communication channel over which a signal is transmitted. The purpose of an equalizer is to compensate for transmission-channel impairment such as frequency-dependent phase and amplitude distortion.

For example, a modem will typically include an equalizer to minimise the effects of distortion resulting from a call being placed over a telephone line.

An equalizer typically compensates for transmission-channel impairment by determining and applying a filter that results in an equalized impulse response having zero intersymbol interference and channel distortion, where typically the equalizer will include filter tap coefficients that are used to define the filtering characteristic of the equalizer, as is well known to a person skilled in the art.

To achieve zero intersymbol interference and channel distortion the convolution of the channel impulse response of the equalizer should ideally equal one at the centre filter tap and have nulls at the other sample points within the filter.

Two main techniques are employed to formulate the filter coefficients: automatic synthesis and adaptation.

In automatic synthesis methods, an equalizer typically compares a received time-domain reference signal with a stored copy of an undistorted training signal. By comparing the received time-domain reference signal with the stored signal a time domain error signal can be determined, which can be used to calculate the tap coefficients for an inverse filter.

For adaptation methods, an equalizer attempts to minimise an error signal based on the difference between the output of the equalizer and an estimate of the transmitted signal, where the estimate is generated by a decision device.

The main drawback of automatic synthesis is the overhead associated with the transmission of a training signal. Typically, training is used to converge a filter at startup as part of an initialization process. Adaptation techniques can then be employed to track and compensate for minor variations in channel response following initialization.

In particular, adaptation techniques involve the generation of a filter output each time a data symbol is received, where the filter output is provided to an input of a decision device. The decision device is used to generate an estimate of the transmitted signal, where the input and output decision device signals are compared. The difference between the input and output decision device signals is then used to form an error signal, which is used to scale the filter tap coefficients to ensure that the correct filtering characteristics are used to filter the next received data symbol.

However, if the original signal is not recovered correctly, for example due to a line glitch, the error signal, which is used to update the filter tap coefficients, can result in positive feedback occurring and for the filter tap coefficients to be updated incorrectly, which can ultimately cause the communication call to fail.

One solution to this problem, as described in U.S. Pat. No. 6,341,360, involves the use of a error detector that freezes filter tap coefficients when the determined error signal exceeds a predetermined threshold. However, this solution has several drawbacks, for example the predetermined threshold value has to be assigned manually, which requires user intervention and, further, requires a decision to be made as to an acceptable level of false alarms.

Accordingly, it is desirable to improve this situation.

In accordance with an aspect of the present invention there is provided an equalizer and a method for filtering a signal according to the accompanying claims.

This provides the advantage of minimising the risk of filter tap coefficients within an equalizer being modified with an erroneous error signal, for example resulting from a glitch signal, without the need for user intervention.

Typically an erroneous glitch signal will cause a transmitted data packet to be corrupted and consequently the associated data packet check sum will indicate an error. By using the checksum to identify that a data packet has been corrupted the equalizer filter tap coefficients can be prevented from being updated based on incorrect information and the tap coefficients associated with the last received data packet can be used, thereby avoiding the possibility of positive feedback occurring and preventing sharp or dramatic changes to the filter tap coefficients values from their steady state values, thereby allowing the filter to recover more quickly from signal errors.

An embodiment of the invention will now be described, by way of example, with reference to the drawings, of which:

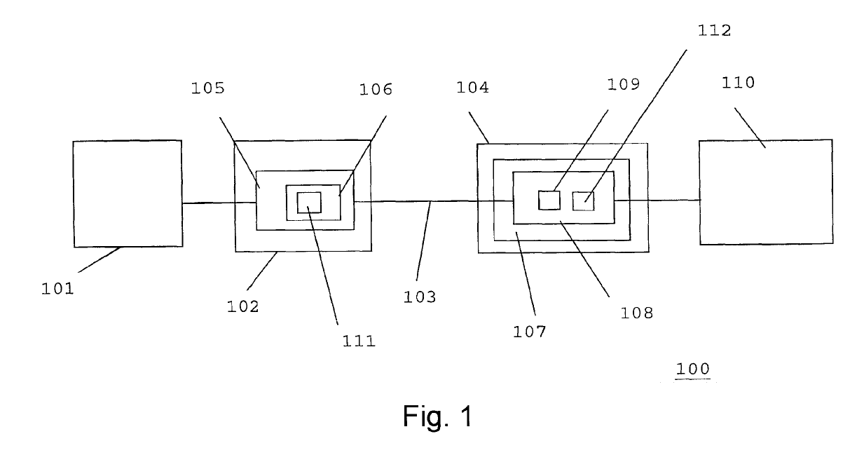

FIG. 1 illustrates a communication system incorporating an equalizer according to an embodiment of the present invention;

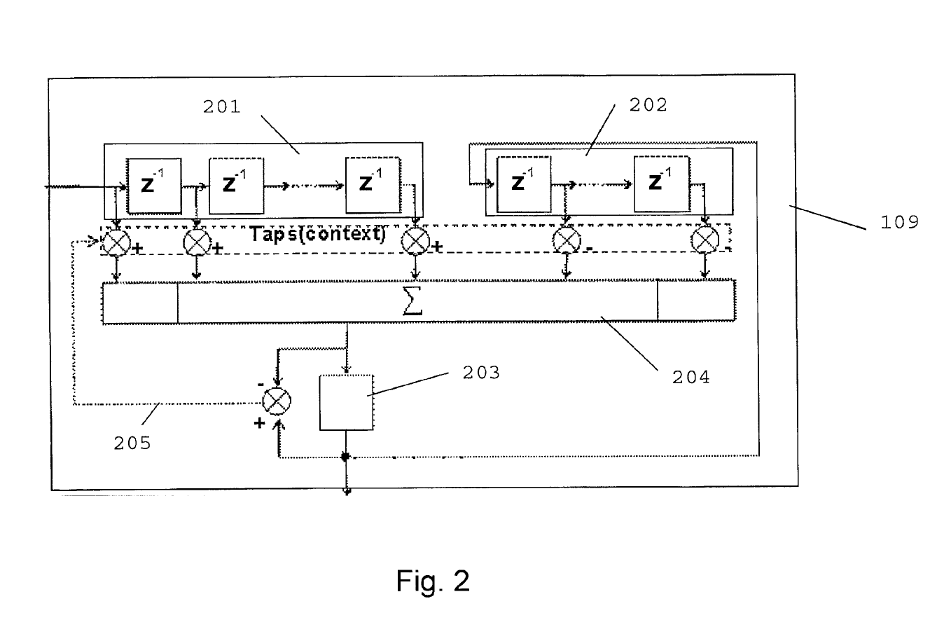

FIG. 2 illustrates an equalizer according to an embodiment of the present invention.

FIG. 1 illustrates a communication system 100 incorporating a message source 101 attached to a first modem 102, where the first modem is arranged to modulate a data packet received from the message source 101 for transmission over a communication channel 103 (i.e. a communication link) to a second modem 104, where the second modem 104 is arranged to receive and demodulate the transmitted data packet. The message source 101 could be any suitable data source, for example an Internet Service Provider, a telephone or a computer, where the type of data transmitted from the first modem 102 to the second modem 104 could be for use in any appropriate application, for example speech, video or alpha numerical characters.

The data generated by the message source 101 is provided to the first modem 102. The first modem 102 includes a transmitter 105 having a signal processor block 104 that incorporates a transport block 111, where the transport block 111 is arranged to format the received data into data packets, which includes an error code, for example a checksum such as a cyclic redundancy check CRC in accordance with the an Link Access LAPM Protocol transport layer according to the V.42 data communication over telephone network standard. For the purposes of the present embodiment the first modem 102 and second modem 104 can be considered as data circuit-terminating equipment DCE in the context of the V.42 LAPM standard.

The transmitter 105 of the first modem 102 is arranged to encode and modulate the data received from the message source 101 that is to be transmitted to the second modem 104 using an appropriate modulation technique,, for example pulse code modulation, and converting received digital data into an analogue signal, as is well known to a person skilled in the art.

The second modem 104 includes a receiver 107, which includes a signal processing block 108 having an equalizer 109 and a transport block 112, where the transport block 112 is in accordance with the V.42 LAPM standard.

The signal processing block 108 is arranged to receive and convert the transmitted analogue signal into digital form and to demodulate and decode the data transmitted by the first modem 102, with the equalizer 109 being arranged to compensate for transmission channel impairment, as described below.

The transport block 112 is arranged to receive the transmitted data packets recovered by the receiver 107. The transport block 112 is then arranged to assemble received data in digital form and provide error checking by calculating the check sum for each received data packet.

As would be appreciated by a person skilled in the art, the communication channel 103 between the first modem 102 and the second modem 104 can take any suitable form, for example a wired or wireless communication link.

Upon successful demodulation and recovery of the received data packet data by the second modem 104 the recovered data packet is output to a data terminal equipment DTE 110.

As stated above the signal processing block 108 includes the equalizer 109, which will now be described in greater detail, where for the purposes of the present embodiment the equalizer 109 is configured as a decision feedback equalizer DFE, however any equalizer that requires the updating of tap coefficients could be used.

As shown in FIG. 2, the equalizer 109 includes a feedforward section 201, a feedback section 202 and a slicer 203.

The feedforward section 201 is arranged to receive the data transmitted by the first modem 102 via an analogue to digital converter ADC (not shown), where the ADC converts the transmitted analogue signal back into the digital domain. The data packets are received as data symbols, as is well known to a person skilled in the art. The feedforward section 201, which could be either a finite impulse response FIR filter or an infinite impulse response IIR filter, has its filter characteristics defined by tap coefficients, as is well known to a person skilled in the art.

The slicer 203 is arranged to convert received digital samples into indices by comparing received digital samples with thresholds that are half way between indexed reference signal levels, and produce soft decisions and hard decisions, where the soft decisions have the inter symbol interference removed and the hard decisions represent the actual symbols.

The feedback section 202 has its filter characteristics defined by tap coefficients, as is well known to a person skilled in the art.

To allow the equalizer filters 201, 202 to generate a soft decision, via the slicer 203, and remove the effect of residual inter symbol interference on detected symbols the output of the feedback section 202 is subtracted from the output of the feedforward section using a summer module 204.

The hard decisions generated by the slicer 203 are fed into the feedback section 202 to remove their effect on future symbol estimates. The coefficients of the feedforward and feedback sections 201, 202 are continuously adjusted in accordance with decision feedback algorithms, as is well known to a person skilled in the art.

An error signal 205 generated by the difference between the soft decision and hard decision is used to update the tap coefficients associated with the feedforward section 201 and feedback section 202, as is well known to a person skilled in the art.

The output from the equalizer 109 provides received symbols to the transport block 112.

Although the signal processing block 108 of the second modem 104 includes additional components, for example an automatic gain control module (not shown) and a two stage interpolator (not shown) for matching the sample rate of the modem to the network, as these are well known to a person skilled in the art these components will not be described in any further detail.

The recovered data packet is received by the transport block 112, where the transport block 112 is arranged to determine whether the checksum associated with the data packet is correct, as in accordance with the V.42 LAPM protocol.

If the checksum is correct the transport block 112 arranges for the data packet to be transmitted to the DTE 110.

If the checksum is incorrect (i.e. an error has been identified within the data packet) it is assumed that the data packet error has occurred as a result of a line glitch and the transport block 112 is arranged to provide tap coefficients to the equalizer 109 corresponding to a correctly received data packet, for example the reloading of tap coefficients that correspond with the tap coefficients for the feedforward section 201 and the feedback section 202 for a previously received data packet. Additionally, in accordance with the V.42 standard the first modem 102 (i.e. the transmitting modem) is requested to retransmit the data packet. Consequently, by using previously used tap coefficients this prevents the equalizer tap coefficients for the feedforward section 201 and the feedback section 202 from being updated with erroneous values resulting from signal values resulting from a line glitch.

From a software perspective the equalizer 109 can be considered as containing a computer code segment for implementing the required algorithms and procedures described above, with a data segment for storing temporary variables and stack segments for supporting the running of specific math/filter routines. The stack memory segments would be used to support software procedure calls with the data memory segment being used for storing continuously modified values of tap coefficients, input data and other variables. As the code memory segment is not changed during run-time, for example during the filtering process performed by the equalizer 109, other memory segments can be considered as equalizer context. Consequently, by using saved earlier equalizer context it is possible to replace tap coefficients that could cause positive feedback to occur.

The above described functionality can be implemented using two operating primitives, for example ‘get’ and ‘set’ equalizer context. For example, if the equalizer 109 is implemented as a non interrupted block (without stack), the two primitives could be reduced to primitives of save and restore tap coefficients. Accordingly, in this configuration, the equalizer context can be considered as tap coefficient values.

The transport block 112 is arranged to perform the updating of the equalizer context via the use of the additional primitives ‘get’ context and ‘save’ context commands. However, as would be appreciated by a person skilled in the art other means for storing and reloading equalizer context could be used.

The transport block 112 includes means for check sum verifications and identification of last received packet. For example, all LAPM packets have to have a frame check sequence field.

The reception of a data packet by the transport block 112 results in a call of one of the primitives (i.e. either the ‘get’ latest good equalizer context when an error free packet is received, or ‘set’ earlier saved good equalizer context if an error has been identified in a received data packet).

The ‘get’ context command causes the equalizer context including tap coefficient values associated with a data packet to be stored in dedicated transport block memory (not shown).

The ‘save’ context command causes the equalizer context associated with a previous data packet to be restored (i.e. previous tap coefficients stored as a result of a ‘get’ context command for a previously received data packet).

Consequently, as stated above the transport block 112 is arranged to use the ‘get’ context to maintain copies of equalizer context in memory (not shown) and the ‘save’ context to reload previously stored equalizer context to the equalizer 109 upon detection of a check sum error.

It will be apparent to those skilled in the art that the disclosed subject matter may be modified in numerous ways and may assume embodiments other than the preferred forms specifically set out as described above, for example the above described equalizer 109 could be used to filter any suitable form of transmitted signal and is not restricted for use in a modem, the processing of data could be arranged to be performed external to the modem, for example in a separate computer, or internal to the equalizer 109, and the signal processing block 108 can be any suitable processor.

1. An equalizer comprising:
memory for storing a set of filter tap coefficients for defining the filtering characteristics to be applied to an input signal;
and means for updating the set of filter tap coefficients based on an error signal derived from a difference between a received signal and a filtered signal unless an error code associated with a received data packet indicates an error in the received data packet.

2. An equalizer according to claim 1, wherein if the error code associated with a received data packet indicates an error in the received data packet the set of filter tap coefficients associated with a previously received data packet are used to define the filtering characteristics of the equalizer.

3. An equalizer according to claim 1 or 2, wherein the means for updating is arranged to receive error code information from a link access protocol layer.

4. An equalizer according to any preceding claim, wherein the error code is a checksum.

5. A modem comprising an equalizer according to any preceding claim.

6. A modem according to claim 4, wherein the equalizer is a decision feedback equalizer.

7. A method for filtering a signal, the method comprising:
storing a set of filter tap coefficients for defining the filtering characteristics to be applied to an input signal;
updating the set of filter tap coefficients based on an error signal derived from a difference between a received signal and a filtered signal unless an error code associated with a received data packet indicates an error in the received data packet;
and filtering the input signal using the set of filter tap coefficients when the error code associated with the received data packet indicates an error or using the updated set of filter tap coefficients when the error code associated with the received data packet does not indicate an error.
